(19) United States
(12) Patent Application Publication
(10) Pub. No.: US 2026/0221380 A1
(43) Pub. Date: Jul. 30, 2026

(54) FOCUSED CHARGED PARTICLE BEAM DEVICE WITH A PRECURSOR SOURCE, AND METHOD FOR PROCESSING OR IMAGING SAMPLES

(71) Applicant: TESCAN GROUP, A.S., Brno (CZ)

(72) Inventor: Miroslav RUDOLF, Brno (CZ)

(21) Appl. No.: 19/152,766

(22) PCT Filed: Feb. 2, 2024
(86) PCT No.: PCT/CZ2024/050006

§ 371 Date: Jul. 31, 2025

(30) Foreign Application Priority Data
Feb. 19, 2023 (CZ) PV 2023-63

(51) Int. Cl. H01J 37/26; H01J 37/30

(52) U.S. Cl. CPC H01J 37/261; H01J 37/3002

(57) ABSTRACT

A focused charged particle beam device for processing or imaging samples having a working chamber in which a particle source extends, an optical system for focusing the charged particle beam, and a support for holding the sample to be processed or imaged. At least one nozzle supplies at least one gas extending into the working chamber so that the gas is introduced to the sample to be processed or imaged. The nozzle supplying the gas is connected to a reservoir that contains a superabsorbent polymer with a gas precursor. A method is also described for processing or imaging samples using the device.

### FIELD OF ART

The present invention concerns devices with focused charged particle beam.

### BACKGROUND ART

Focused charged particle beam devices are used for processing samples using a charged particle beam. Sample processing using a focused particle beam may include milling or etching nanostructures on the samples or depositing layers of materials on the samples. In milling or etching, the principle usually consists in individual particles of the charged particle beam striking the surface of the sample, knocking out one or more surface atoms of the sample, a phenomenon called “sputtering” and, in the case of fine removal of surface irregularities or impurities, “polishing”. On the other hand, depositing layers of materials involves the deposition of a layer of molecules on the surface of the sample, which, when irradiated by a charged particle beam, degrade into volatile molecules, which are released into the working chamber environment where they are subsequently removed by a vacuum pumping system, and non-volatile molecules, which remain deposited on the sample in the form of a deposit. However, sputtering is typically slow, as most samples undergo redeposition of the sputtered material back onto the sample whilst sputtering takes place; therefore, auxiliary gases are often used to increase or decrease sputtering efficiency, depending on the type of material being sputtered and the type of auxiliary gas. These auxiliary gases provide molecules that are capable of forming volatile compounds with the material to be sputtered, thereby reducing its redeposition. This allows different samples to be processed more efficiently, where, for example, the auxiliary gas increases the sputtering efficiency of the material to be removed during processing while decreasing the sputtering efficiency of the material not to be removed during processing. Alternatively, in the case of inhomogeneous samples, it may be possible to sputter different materials at the same rate (U.S. Pat. No. 10,886,139B2). In the case of the deposition of layers of material, it is again desirable to have a wide range of gases that can be used under different conditions, for example, at different temperatures or for different chemical compositions of the deposited layer.

These auxiliary gases typically include a wide variety of inorganic and organic chemicals, including halogenated compounds, which are stored in the reservoir in a pure form or in the form of precursor compounds from which the desired auxiliary gas is released, for example, when heated. These auxiliary gases or their precursor compounds may be stored in the reservoir in a solid or liquid form, the solid form being much more preferred. The main disadvantage of the liquid form is that it is more difficult to handle a filled reservoir. Another disadvantage is the danger of releasing the liquid precursor into the working chamber, which is under vacuum (very low pressure). This is because opening the valve links vessels with a large pressure difference, namely the reservoir, at up to atmospheric pressure, and the working chamber, with a high to ultra-high vacuum. When some of the liquid precursor enters the working chamber, the liquid precursor very quickly becomes gaseous, which disturbs the vacuum stability and may even damage the sample or the whole device. Another disadvantage is the risk that the auxiliary gas has a variable release rate due to the changing liquid surface, for example, due to the liquid boiling at reduced pressure or due to ripples on the liquid surface from vibrations or shocks caused by the instrument, the user or environmental influences.

An example of a frequently used auxiliary gas that is a liquid under laboratory conditions is water vapour. Water vapour is a suitable auxiliary gas because it provides sufficient oxygen to facilitate the formation of volatile compounds. Furthermore, water is environmentally neutral. However, the production of vapours, such as water vapour, for a focused charged particle beam device so that the gas, or water vapour, is delivered homogeneously and in sufficient quantity is a problem. As noted above, in general, the use of liquid precursors from which auxiliary gas vapours are subsequently formed is complicated. For example, the use of water itself, which is placed in a reservoir in liquid form and used to release water vapour, is disclosed in U.S. Pat. No. 5,958,799. This method leads to the problems described above. It has, therefore, been proposed to use inorganic salts, also called inorganic mineral sorbents, such as solid ferric iodide hydrate or magnesium sulfate hydrate, as water reservoirs, more homogeneously releasing water in the form of water vapour (U.S. Pat. No. 5,854,488). Magnesium sulfate heptahydrate, commonly called epsomite, is currently used in commercially available focused charged particle beam devices. The disadvantage of this solution is that the water content that can be released from the magnesium sulfate heptahydrate at constant temperature is only a very small fraction by weight, furthermore, the amount of water vapour released from the magnesium sulfate heptahydrate is highly variable over time due to the variability of the binding energies by which the individual molecules in the magnesium sulfate heptahydrate are bound. Moreover, to achieve a vapour pressure comparable to liquid water, it is necessary to intensively heat the magnesium sulphate heptahydrate.

Another case where the use of liquid precursors is very appropriate is, for example, the use described in EP 2402477, which deals with the deposition of carbon on a substrate cooled to temperatures below minus 50° C. Precursors suitable for this purpose are chosen so they have a melting point lower than the temperature of the substrate to avoid condensation of these vapours on the surface of the sample. All precursors referred to in the cited document are gaseous under these conditions. It is difficult to find a suitable precursor which is solid under laboratory conditions and whose vapours have the required physical and chemical properties at minus 50° C. Furthermore, as the working temperature of the sample decreases, the amount of usable solid precursors decreases significantly.

Suitable precursors may be, for example, gaseous and liquid organic solvents meeting the above condition. A major disadvantage of many substances that do not crystallise at the required cryogenic temperatures is that they only exist in the liquid or gaseous state under normal laboratory conditions and at normal atmospheric pressures, and, therefore, they are difficult to handle. One solution may be to cool the precursor reservoir to a temperature at which the precursor is a solid, thereby resolving the complications associated with precursor liquid state. On the other hand, this will not guarantee sufficient precursor vapour pressure at a given temperature for use in combination with a focused beam since the saturated vapour pressure generally decreases logarithmically with temperature.

Another example of liquid precursors for forming auxiliary gases that can be used to adjust the sputtering rate of inhomogeneous surfaces at 20° C. are the compounds listed in U.S. Pat. No. 9,064,811B2, for example, methyl acetate, methyl nitroacetate, ethyl acetate and ethyl nitroacetate.

### DISCLOSURE OF THE INVENTION

The invention provides a new method for storing and using a liquid precursor that releases an auxiliary gas for a focused charged particle beam device. The invention is based on the formation of solid products, in particular, gels, comprising at least one liquid precursor and a superabsorbent polymer.

Suitable precursors are typically inorganic or organic substances which are liquid at an ambient pressure of 101325 Pa (normal atmospheric pressure) and at 50° C. It is particularly preferred that these liquid precursors have a saturation vapour pressure greater than 0.1 kPa at an ambient pressure of 101325 Pa and at 50° C.

Suitable precursors are preferably inorganic or organic substances which are liquid at an ambient pressure of 101325 Pa (normal atmospheric pressure) and at 25° C. It is particularly preferred that these liquid precursors have a saturation vapour pressure greater than 0.1 kPa at an ambient pressure of 101325 Pa and at 25° C.

More specifically, the precursors may be selected from the group consisting of water; liquid C5 to C16 alkanes; liquid C4 to C9 cycloalkanes; liquid aromatics such as benzene, toluene, xylene; liquid esters such as methyl acetate, methyl nitroacetate, ethyl acetate, ethyl nitroacetate; liquid C1 to C9 alcohols such as methanol, ethanol, propanol, isopropanol, butanol; liquid phenols; liquid carboxylic acids such as C1-C12 carboxylic acids, trifluoroacetic acid; and liquid organometallic compounds (e.g. listed in https://www.globalsino.com/EM/page4523.html, e.g. trimethylaluminium, pentaethoxytantalum).

Superabsorbent polymers refer, in particular, to polymers selected from the group of polyacrylates, polyacrylamides, polymethacrylates, polymethylmethacrylates, polyalkylmethacrylates, polyvinyl alcohols, hydroxyalkylpropiophenones, cross-linked polyethylene oxides, polyethylene glycols, polystyrenes, polyurethanes, cellulose, cellulose esters and ethers such as hydroxypropyl cellulose, starch, xanthan gum, and mixtures of these polymers. Hydrophilic superabsorbent polymers are also called hydrogels. Superabsorbent polymers are capable of swelling and absorbing or adsorbing the corresponding precursors. For example, hydrogels can take up to 300 times their weight of distilled water. After swelling, the superabsorbent polymers form a gel.

Preferably, interpenetrating polymer networks (IPNs), comprising two or more polymers, may be used as superabsorbent polymers, their polymer networks being interpenetrated but not chemically bonded. For example, an IPN comprising sodium polyacrylate and polyacrylamide may be advantageously used. The sorption capacity of an absorbent (superabsorbent polymer) is mainly related to the size of its active surface or porosity, its cross-linked structure, and its ability to interact with the precursor, such as superhydrophilicity or superhydrophobicity.

Superabsorbent polymers are known and widely used, for example, in hygiene products and in agriculture.

It is preferred to use superabsorbent polymers that can hold at least 5 g of precursor per 1 gram by weight of the superabsorbent polymer under normal conditions (pressure 101325 Pa and temperature 20° C.).

Preferably, the superabsorbent polymer for storing polar substances, such as water, is sodium polyacrylate or potassium polyacrylate. These polymers have a molecular weight Mw typically within the range of 1 000 g/mol to 90 000 g/mol.

Preferably, the superabsorbent polymer for storing non-polar organic substances, such as liquid C5-C16 alkanes or C4-C9 cycloalkanes, is polymethyl methacrylate or polystyrene.

Preferably, the superabsorbent polymer for storing polar organic substances, such as alcohols, is a polyacrylamide, such as poly(N-isopropylacrylamide), or an IPN containing polyacrylate and polyacrylamide.

Preferably, the superabsorbent polymer for storing aromatic compounds, esters, carboxylic acids or organometallic compounds, is polystyrene, polymethyl methacrylate or cellulose.

The following table shows non-limiting examples of suitable superabsorbent polymers (absorbents) for specific precursors:

| Precursor | Absorbent 1 | Absorbent 2 |
|---|---|---|
| water | polyacrylate | |
| toluene | cellulose | polystyrene |
| ethyl acetate | polyacrylate | polystyrene |
| ethanol | polyacrylamide | polyacrylate |
| isopropanol | polyacrylamide | polyacrylate |
| hexane | cellulose | cellulose (cotton) |
| cyclohexane | cellulose | cellulose (cotton) |
| acetic acid | polyacrylate | polyacrylamide |

Epsomite, as a representative of an inorganic salt hydrate, is now commonly used as a solid precursor of water vapour for commercially available focused charged particle beam devices, although it has quite a few disadvantages. The first disadvantage is that it is only capable of storing an amount of water equivalent to about 50% of the total weight of the epsomite. At a constant temperature of less than 50° C., the epsomite releases only about 7% of the available water, nor does it do so homogeneously.

Superabsorbent polymers can contain many times more water than hydrates of inorganic salts, including epsomite, for the same weight of material contained in the reservoir. Surprisingly, however, superabsorbent polymers have also been shown to release precursor gases, e.g. water vapour, uniformly and homogeneously over a longer time period than epsomite, which increases the reproducibility of the results obtained, for example, in sample processing. This is at least in part due to the fact that superabsorbent polymers have a stable partial water pressure (more generally, precursor pressure) throughout the time the auxiliary gas is being produced and introduced into the working chamber. The water bound in the gel retains its physical properties, such as saturation vapour pressure, because the water molecule is very weakly bound to the superabsorbent polymer. Unlike superabsorbent polymers, the release of water from epsomite at constant temperature is not ideal due to the partial pressure of the precursor in the working chamber. The partial pressure of water in the working chamber when using epsomite and a constant reservoir temperature, for example, in the range of 25° C. to 35° C., is not constant over time, which is probably due to various structural defects in the crystal structure of epsomite and hence various variations in the binding energies of the water molecules in the crystal. In contrast to epsomite, all water molecules in the superabsorbent polymer gel are bound in the same way. Thus, they all need the same activation energy (same temperature) to be released from the structure. The maximum water release from the superabsorbent polymer is, therefore, between 90 and 99% of the weight of the gel at room temperature. Moreover, the superabsorbent polymer does not have a crystalline structure, and the time course of the precursor partial pressure in the working (vacuum) chamber shows that the partial pressure of the water vapour is more stable over time than in the case of water release from epsomite, leading to a very valuable characteristic-better repeatability of a given application performed in the working chamber region of the microscope. Superabsorbent polymers are also much easier to rehydrate than inorganic salts.

Superabsorbent polymers also allow to achieve a higher saturated vapour pressure than epsomite, or a comparable gas pressure, at the same temperature compared to the release from the free surface of a liquid precursor, however, they have the advantage of maintaining the solid state of the superabsorbent polymer with the precursor. They allow a longer gas introduction time to the device, so there is no need to interrupt processing, and there is no need to frequently change the reservoir content.

Superabsorbent polymers provide similar advantages as described herein for water or water vapour also for other liquid precursors of auxiliary or working gases or for the actual auxiliary or working gases.

Accordingly, in one aspect, the subject of the invention provides a focused charged particle beam device for sample processing or sample imaging comprising a working chamber into which a charged particle source is beamed and further comprising an optical system (e.g., a lens system) for focusing the charged particle beam and a support for holding the sample to be processed or imaged, wherein at least one nozzle supplying at least one gas extends into the working chamber such that the gas can be introduced into the vicinity of the sample to be processed or imaged. According to the invention, the nozzle supplying the gas is connected to a reservoir containing a superabsorbent polymer with an auxiliary and/or working gas precursor. Further, the device may include at least one valve for controlling the amount of gas supplied. The working chamber may further comprise at least one imaging or working lens tube. The auxiliary and/or working gas precursor is absorbed within the superabsorbent polymer.

The operating conditions in the device reservoir are defined by the operating temperature, which may be a normal laboratory temperature or a controlled temperature of less than 30° C., less than 50° C., or less than 80° C. The objective is to achieve a working chamber pressure between 1·10⁻¹ Pa and 1·10⁻⁵ Pa, depending on the type of application required. The magnitude of the working pressure of the gas in the working chamber depends mainly on the volume of the working chamber and the performance of the pumping system, the characteristics of the system of tubing for introduction of the precursor, in particular the length of the tubing, the diameter of the nozzle capillary, the control mechanisms, and the saturation vapour pressure of the precursor in the reservoir. The saturation vapour pressure of the auxiliary or working gas in the reservoir is primarily influenced by the temperature of the reservoir.

Some focused charged particle beam devices do not have reservoirs suitable for gaseous or liquid precursors and handling a solid or at least a gel or highly viscous superabsorbents with precursors is always safer and easier, as it greatly reduces the risk of unwanted release of liquid precursor into the environment or into the working chamber environment. In this case, a reservoir refers to any space where a superabsorbent polymer with a precursor (in solid or gel form) can be introduced.

Optionally, the device may further comprise a signal particle detector (secondary or reflected or signal particles), which allows to display the surface of the sample to be processed and thus monitor and control the progress of the processing.

Signal particles can be electrons, ions or photons.

The device may also optionally include injectors for further auxiliary gases, such as halogenated gases, arranged such that these further auxiliary gases are introduced to the sample to be processed. These auxiliary gases may also be produced from reservoirs containing a superabsorbent polymer with a gas precursor.

The device preferably comprises a means for heating the reservoir over a temperature range of 15° C. to 100° C. This means may be, for example, an electric resistance coil or a heating nest.

In some embodiments, the device may be configured to operate in cryogenic mode, i.e. at a sample temperature inside the working chamber being below 0° C.

The focused charged particle beam device may be, for example, a scanning electron microscope (SEM), a focused ion beam (FIB) device, a broad ion beam (BIB) device, a combined FIB/SEM device, or a transmission electron microscope (TEM). The device may be used for processing or imaging samples, such as biological samples, electrically charged samples, or samples sensitive to hydrocarbon contamination.

A “working chamber” refers to a vessel in which the pressure is less than 500 Pa, preferably less than 1 Pa, more preferably less than 0.001 Pa. Preferably, the pressure is about 0.00001 Pa.

In another aspect, the object of the invention is use of the superabsorbent polymer as a reservoir of liquid precursors for generating an auxiliary and/or working gas in a device for processing or for imaging samples with a focused charged particle beam.

In yet another aspect, the object is a method for processing or imaging samples using a focused charged particle beam, said method comprising the following steps:
introducing a gas into a working chamber to the sample to be processed or imaged, wherein the gas is generated by release from a superabsorbent polymer saturated with a liquid precursor of the gas,
   and simultaneously or subsequently
irradiating by a focused charged particle beam the desired part of the surface of the sample to be processed or imaged which has been inserted in the working chamber.

The release of the gas from the superabsorbent polymer is achieved by the natural vapour pressure over the polymer with the absorbed precursor of the gas, or the reservoir can be heated to achieve the desired level of gas release from the superabsorbent polymer.

The sequence of the steps can be repeated as needed.

Thus, prior to processing or imaging the sample, a superabsorbent polymer swelled by the liquid precursor of the gas is introduced into the reservoir of the device and, or a superabsorbent polymer is introduced into the reservoir and subsequently swelled by the liquid precursor of the gas in the reservoir. The superabsorbent polymer then releases the precursor is a gaseous state, which is the desired (auxiliary or working) gas. The rate of release of the precursor can be influenced by temperature, thus the superabsorbent polymer can be heated if necessary. The released gas is introduced into the device working chamber in a controlled manner via at least one valve, and in the working chamber the gas acts as an auxiliary or working gas to influence sample processing or sample imaging.

A focused beam of charged particles is typically used to scan or raster scan, i.e., run over, the surface of the sample being processed or imaged.

The sample processing may preferably include milling, etching, grinding, polishing or deposition.

The samples may include electronic components, such as semiconductor components, electrical battery components, steels and alloys, ceramics, glass, building materials, polymers, wood, textiles, paper, rocks, minerals, or biological materials (e.g. for processes carried out at temperatures below 0° C.). Samples may need to be milled or etched with a charged particle beam to form a predetermined pattern or to be made into, for example, slats for further observation, or it may be needed to deposit a layer on the samples. Alternatively, the samples may be subjected to observation.

Furthermore, the sample may be carbon-contaminated materials or, for example, carbon-contaminated metallic deposits, wherein processing means the removal of contaminants from the sample by their reaction with oxidants, wherein, for example, water vapour, as an oxidant, increases the cleaning efficiency without significantly contributing to sputtering the desired material.

Another example is the milling of polyamide or polyimide on metal (e.g. aluminium), where water vapour increases the milling efficiency of the polyamide or polyimide but reduces the milling efficiency of the metal.

Another example is acetic acid esters as auxiliary gases and their use in unifying the rate of sputtering dissimilar materials such as copper and dielectrics.

A metal-containing precursor (for example, an organometallic compound of iron, gold, tungsten, aluminium, tantalum, or platinum) can be used to deposit this metal on the sample.

Samples to be imaged (especially when using water vapour) may be, for example, biological samples, electrically charged samples, or samples sensitive to hydrocarbon contamination.

When used for water or water vapour, the superabsorbent polymer gel has approximately three times the saturated vapour pressure of water at room temperature compared to the hitherto used epsomite. The higher partial pressure of water in the sample area (area in the vicinity of the sample) has a positive effect, for example, on the following applications: The addition of water in combination with a charged particle beam increases the etching rate of polyamide (used in the semiconductor industry as a capping layer) compared to using just a charged particle beam with the same parameters. The higher partial pressure of water in the sample area effectively increases the etching rate. It also improves electrical charge dissipation in applications where the sample in the working chamber is charged. The higher water partial pressure mitigates hydrocarbon contamination of the sample when used in conjunction with an electron beam.

Another advantage of superabsorbent polymers (in the case of water or water vapour) is that when the water vapour pressure in the sample area needs to be adjusted using the temperature of the superabsorbent polymer with water in the reservoir, the superabsorbent polymer does not have a critical point whereupon the pressure changes dramatically with a small change in temperature. This phenomenon would only occur when the decomposition temperature of the superabsorbent polymer is reached.

Yet another advantage of using superabsorbent polymers is that they can immobilize a liquid precursor under working conditions, thereby facilitating its use and reducing the risks associated with using liquid precursors, all with very little or no change in the partial pressure of the gas generated from the precursor adsorbed or absorbed within the superabsorbent polymer compared to the partial pressure of a gas generated from a free liquid precursor.

The terms “sample” and “material” are used interchangeably in this text as well as in the relevant field. Where a distinction is made between the two, then material is the material being sputtered or deposited, and the sample is the entity from which the material is sputtered, onto which it is deposited, or which is imaged.

### BRIEF DESCRIPTION OF DRAWINGS

FIGS. 1A and 1B illustrate examples of a device in which the present invention can be used. FIG. 1C shows a detail of the device reservoir.

FIG. 1 shows a comparison of two water precursors, sodium polyacrylate (PA) hydrogel and epsomite, in terms of water availability for a given reservoir.

FIG. 2 shows a recording of monitoring of the partial pressure of water in the working chamber at a constant temperature for two water precursors: the first is a hydrogel formed from 0.1 g of superabsorbent polymer+1 g of water, and the second is 2 g of epsomite. Occasional pressure reduction serves as a control of the system base pressure.

FIG. 3: Dependence of etching rate acceleration for a poly(methyl methacrylate) (PMMA) sample etched using Ga ions using water vapour on water vapour pressure inside the microscope working chamber. The etching rate is normalized to the value 1, at which the etching rate corresponds to the rate without using water vapour.

FIG. 5: Comparison of water vapour pressure generated from a liquid precursor alone vs. from a liquid precursor within a superabsorbent polymer (polyacrylate). Absorption of the precursor into the superabsorbent polymer has very little effect on pressure. Thus, in terms of its saturation vapour pressure, the liquid absorbed within the superabsorbent corresponds to the saturation vapour pressure of the liquid itself. For both cases, the pressure was measured inside the working chamber of an identical microscope (same chamber volume, same temperature inside the chamber, same pumping system). The experiment was conducted with the control valves of the vapour injection system fully open with the same amount of water (1 ml) in both precursors. The conditions outside the working chamber were T=22° C., atmospheric pressure.

FIG. 6 shows an example of platinum deposition on a sample under various conditions (Example 4).

FIG. 7 shows an example of carbon deposition on a cryogenic sample using the invention.

FIG. 8 shows a comparison of the vapour pressure of toluene in the working chamber, wherein the vapour is generated from a liquid precursor alone and from a liquid precursor absorbed within cellulose.

### EXAMPLES OF CARRYING OUT THE INVENTION

### Example 1: A Device for Processing or Imaging Samples

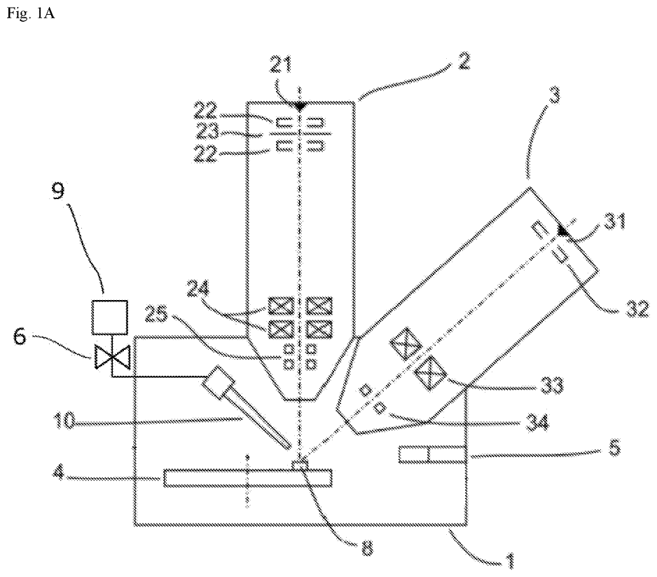

An example of a device according to the invention is shown in FIG. 1A. This device is an example of a FIB/SEM device. A scanning electron microscope tube 2, comprising an electron source 21, a condenser 22, an aperture 23, an objective lens 24, and raster coils 25, is placed on a working chamber 1. Further, a focused charged particle beam tube 3 comprising a charged particle source 31, a condenser 32, an objective lens 33, and a raster system 34, is placed on the working chamber 1. In the working chamber 1, there is a support 4 for holding the sample 8 to be processed or imaged. The working chamber further comprises a nozzle 10 for introducing water vapour, which is connected to the reservoir 9 via a valve 6. The reservoir 9 contains a superabsorbent polymer saturated (swelled) with a liquid precursor (e.g., water). The device is further fitted with a signal particle detector 5.

FIG. 1B shows another example of the device, which differs from FIG. 1A by the presence of an additional nozzle 11 for a second auxiliary gas. The nozzle 11 is connected via a valve 13 to a reservoir 12. The reservoir 12 may also contain a superabsorbent polymer saturated with a liquid precursor. Typically, the precursors in reservoirs 9 and 12 are different from each other.

FIG. 1C shows a schematic depiction of a possible design of the reservoir 9. The reservoir contains a superabsorbent polymer 91 with a precursor, above which is an empty space 92. The bottom of the reservoir is provided with a means 93 for thermal regulation. Furthermore, the reservoir is provided with an outlet tube 94 leading from the empty space 92 to a valve 6. The gas released from the super-absorbent polymer 91 into the empty space 92 passes through the outlet tube 94, and is introduced into the working chamber as required, as controlled by the valve 6. In the particular embodiment used in these experiments, the diameter of the capillary 94 was 3 mm and the aperture 95 of the nozzle 10 was set successively at 50 μm, 30 μm, 25 μm and 20 μm. With a nozzle aperture diameter of 50 μm, the water vapour pressure in the chamber at 30° C. was 2.7·10⁻³ Pa, with an aperture of 30 μm 1·10⁻³ Pa, with an aperture of 25 μm 7·10⁻⁴ Pa, and with an aperture of 20 μm 4·10⁻⁴ Pa.

### Example 2: Monitoring Vapour Partial Pressure Using Epsomite Vs. Super-Absorbent Polymer

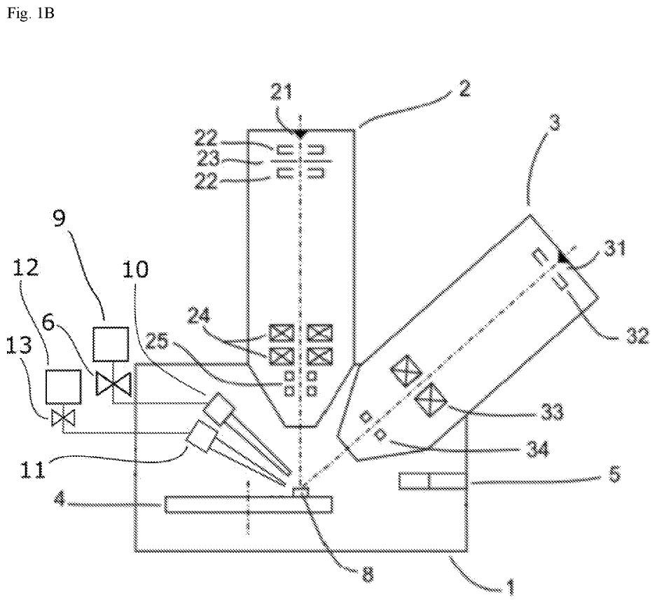

FIG. 2 shows a comparison of two water precursors, a super-absorbent sodium polyacrylate (PA) hydrogel saturated with water and epsomite, in terms of water availability for a given reservoir volume. Considering the dehydration of epsomite at constant epsomite temperature (<50° C.), which proceeds according to the following equation MgSO₄·7H₂O->MgSO₄·6H₂O+H₂O, the available amount of water vapour (H₂O on the right-hand side of the equation) is only 7% by weight of the original precursor, whereas the available amount of water in the hydrogel (a mixture of 10 wt. % sodium polyacrylate+90 wt. % H₂O) is an order of magnitude greater.

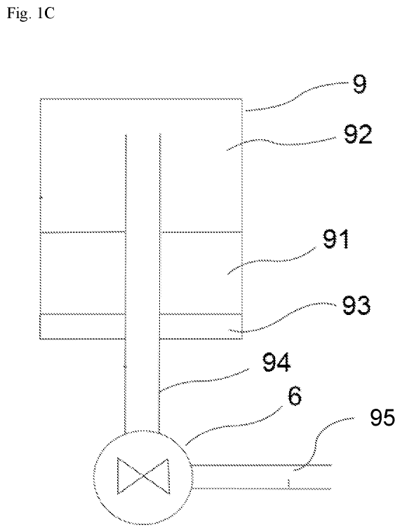

As an example, FIG. 3 shows a time record of the vapour pressure dependence of water measured by a vacuum gauge placed inside the microscope working chamber. The comparison is made for two solid-phase water precursors, 2 g of epsomite and a mixture of 0.1 g sodium polyacrylate+1 g H₂O. Both precursors occupy the same volume. Sudden pressure drops are caused by closing the reservoir to control the stability of the base pressure inside the working chamber. Both pressure waveforms correspond to the two marked points in the graph in FIG. 2. The precursor sodium polyacrylate+H₂O at the same volume as epsomite will provide approximately 7 times more water vapour than epsomite. The reservoir temperature in both cases was 30° C.

### Example 3: Milling Polyamide by Ga Ions

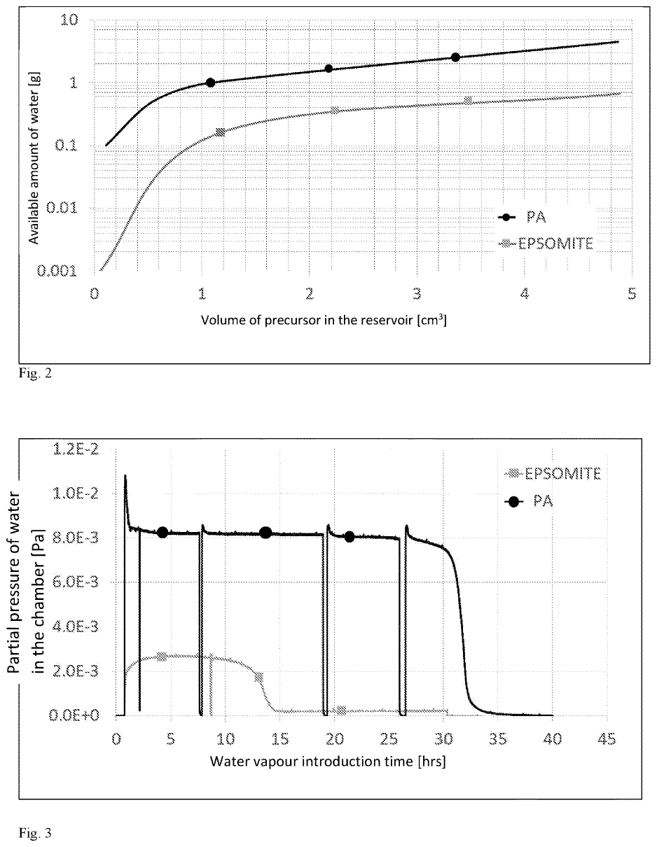

In a further example of use, the sputtering rates of polyamide were compared while releasing water vapour. The measurements show that the sputtering rate is proportional to the water vapour pressure measured inside the working chamber of the device. When using the precursor (water) absorbed in the superabsorbent (polyacrylate) vs. contained in the epsomite, different reservoir temperatures had to be set to achieve similar water vapour pressures. While in the case of the water precursor in the superabsorbent, a pressure of 1·10⁻² Pa was achieved at a reservoir temperature of 30° C. and pure water achieved a comparable pressure of 1·10⁻² Pa (FIG. 5), the epsomite precursor provided a pressure of just 1·10⁻³ Pa under the same conditions. These values correspond to a relative etching rate of 12 for free water or water absorbed in the superabsorbent and an etching rate of 7 for epsomite under the same conditions.

FIG. 4 shows a comparison of the etching rates of a polymethyl methacrylate (PMMA) sample using Ga ions with the aid of water vapour introduced to the sample area located inside the working chamber of the microscope, which is one application of the use of water vapour in the vacuum region of an electron microscope. Two precursors, epsomite and a sodium polyacrylate+H₂O mixture, are compared. Measurements of the etching rates are made under different water vapour pressures inside the microscope. The water vapour pressure was controlled by the temperature of the reservoir. The etching rate without water vapour is normalized to a value of 1. It can be seen from the graph that the acceleration of etching of the PMMA sample using both precursors has a similar trend. This confirms that the precursor sodium polyacrylate+H₂O can be used for the application.

Measurement parameters: ion beam energy Ga⁺ 30 kV, ion current 150 pA.

### Example 4: Removal of Contaminants During Platinum Deposition

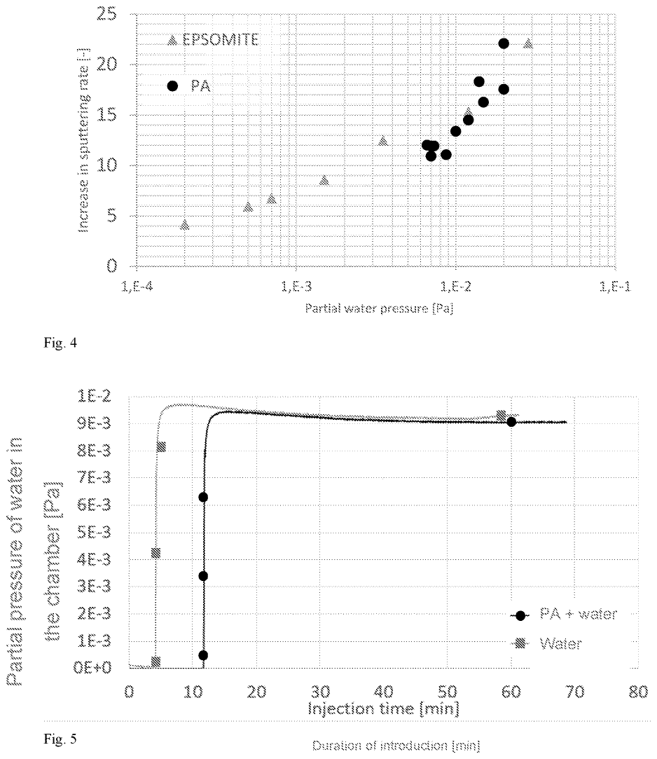

Another example of use is the deposition of platinum while introducing water vapour. The system comprises two gas injection systems, one reservoir containing a water vapour precursor and the other reservoir containing a vapour generation precursor for the deposition of platinum, trimethyl(methylcyclopentadienyl) platinum (IV). A separate nozzle is attached to each reservoir to introduce the working gas vapour into the vicinity of the sample in the working chamber. Platinum deposition was carried out for 10 minutes. The amount of precursor in the reservoir was 1 g. The working temperature of the platinum precursor was 55° C. Water was introduced together with the platinum precursor, either from the reservoir where it was absorbed in the superabsorbent or from the reservoir where it was a free liquid (water alone). There was no significant difference with the chemical composition of the deposit whether using water in the superabsorbent or water alone. When water vapour was not used at all, the platinum content of the composite was 20% lower. The higher amount of platinum in the deposits can also be qualitatively observed using signal electrons (FIG. 6), where deposits with higher brightness also contain more platinum.

Measurement parameters: beam energy 30 kV, probe: Ga ions, probe current 250 pA, probe aperture: 130 μm, exposure pitch 100 nm, irradiation area 100 nm, dwell time 200 ns, scanning zig-zag, reservoir temperature 40° C.

FIG. 6 shows an example of platinum deposition on a sample under different conditions.

### Example 5: Carbon Deposition on a Cryogenic Sample

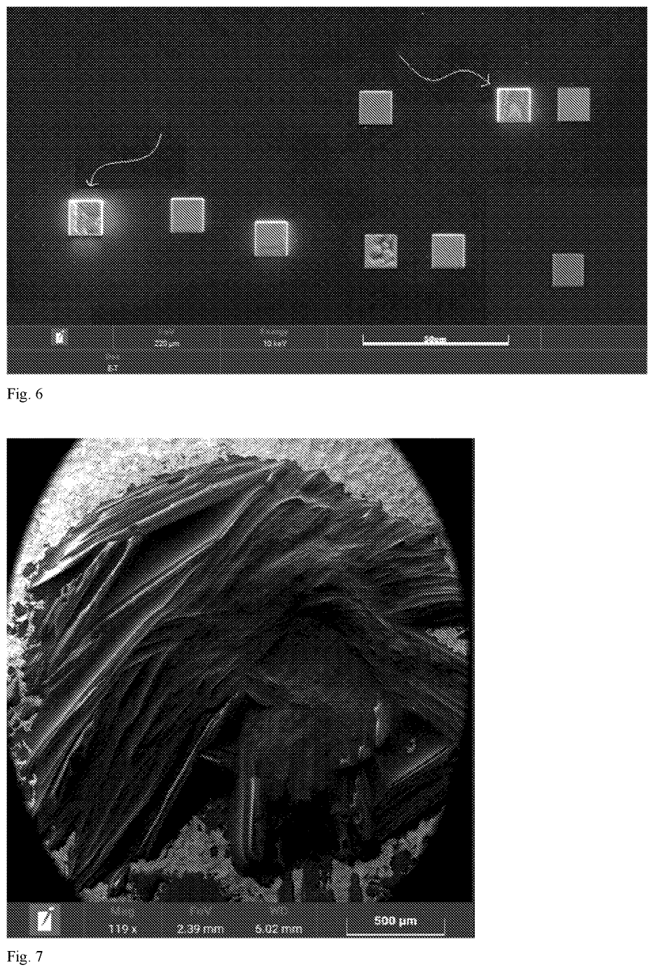

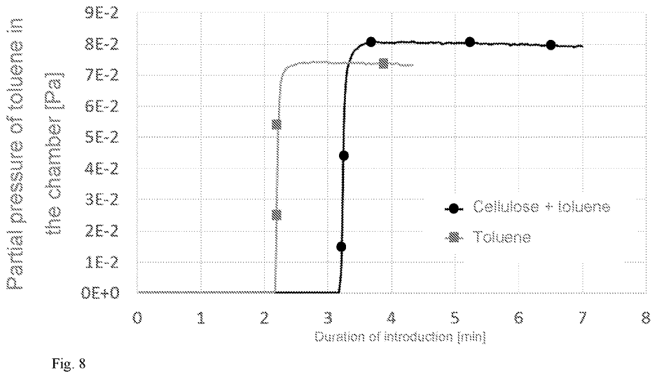

Another example is the deposition of carbon onto a cryogenic sample (cooled to −80° C.). Toluene was used as a precursor gas for carbon deposition. Toluene, which is a liquid under laboratory conditions, was stored at laboratory temperature in a reservoir immobilized in cellulose. The result showed that at laboratory temperature, toluene absorbed in cellulose generates enough vapour to be used for carbon deposition. The vapour pressure generated from cellulose and the vapour pressure from free toluene were comparable. FIG. 7 shows the generated carbon deposits on the sample and FIG. 8 shows a comparison of the saturated vapour pressure of free toluene (toluene alone) and toluene absorbed in cellulose. Sorption to the superabsorbent has only a very small effect on the pressure. The liquid absorbed in the cellulose is, therefore, equal to the unabsorbed liquid in terms of saturation vapour pressure. The pressure was measured inside the working chamber of an identical microscope (the same chamber volume, the same temperature inside the chamber). The experiment was carried out with the control valves fully open at the same amount of toluene (1 g) and toluene in cellulose (1 g). The conditions outside the working chamber were standard, T=25° C., atmospheric pressure.

The following table shows an estimate of the gas pressure for the working chamber using different precursors at 30° C. and an aperture size of 50 μm. It also shows the preferred type of absorbents (superabsorbent polymers) for the precursors.

| | | | Pressure in the | | | |
|---|---|---|---|---|---|---|
| | VP | Aperture | working | T | | |
| Precursor | (kPa) | (um) | chamber (Pa) | (° C.) | Absorbent 1 | Absorbent 2 |
| water | 4.245 | 50 | 0.003 | 30 | polyacrylate | |
| toluene | 4.666 | 50 | 0.003 | 30 | cellulose | polystyrene |
| ethyl acetate | 16.02 | 50 | 0.010 | 30 | polyacrylate | polystyrene |
| ethanol | 11.99 | 50 | 0.008 | 30 | polyacrylamide | polyacrylate |
| isopropanol | 8.17 | 50 | 0.005 | 30 | polyacrylamide | polyacrylate |
| hexane | 25 | 50 | 0.016 | 30 | cellulose | cotton/cellulose |
| cyclohexane | 16.23 | 50 | 0.010 | 30 | cellulose | cotton/cellulose |
| acetic acid | 2.6 | 50 | 0.002 | 30 | polyacrylate | polyacrylamide |

1. A focused charged particle beam device for processing or imaging a sample, said device comprising:
a working chamber (1) into which a particle source extends, and further comprising an optical system (3) for focusing the charged particle beam and a support (4) for holding a sample (8) to be processed or imaged,
wherein at least one nozzle (10, 11) supplying at least one gas extends into the working chamber (1) so that the gas is introduced to the sample (8) to be processed or displayed, and
wherein the nozzle (10, 11) supplying the gas is connected to a reservoir (9, 12) containing a superabsorbent polymer with a gas precursor.

2. The device according to claim 1, wherein the superabsorbent polymer is selected from a group consisting of polyacrylates, polyacrylamides, polymethacrylates, polymethylmethacrylates, polyalkylmethacrylates, polyvinyl alcohols, hydroxyalkylpropiophenones, cross-linked polyethylene oxides, polyethylene glycols, polystyrenes, polyurethanes, cellulose, cellulose esters, cellulose ethers, starch, xanthan gum and their mixtures.

3. The device according to claim 1, wherein the gas precursor is selected from the group consisting of water; liquid C5 to C16 alkanes; liquid C4 to C9 cycloalkanes; liquid aromatics such as benzene, toluene, xylene; liquid esters such as methyl acetate, methyl nitroacetate, ethyl acetate, ethyl nitroacetate; liquid Cl to C9 alcohols such as methanol, ethanol, propanol, isopropanol, butanol; liquid phenols; liquid carboxylic acids such as C1-C12 carboxylic acids, trifluoroacetic acid; and liquid organometallic compounds, where the definition of “liquid” refers to a pressure of 101,325 Pa and a temperature of 50° C., preferably at 25° C.

4. The device according to claim 1, which further comprises at least one valve (6, 13) for controlling the amount of gas supplied, located between the reservoir (9, 12) and the nozzle (10, 11).

5. A method of processing or imaging a sample using a focused charged particle beam in the device according to claim 1, wherein the method includes the following steps:
introducing gas to the sample being processed or imaged (8) wherein the sample is placed in the working chamber (1) of the device according to claim 1,
wherein the gas is generated from a superabsorbent polymer saturated with a liquid or gaseous gas precursor, and
irradiating by a focused charged particle beam the desired part of the surface of the sample (8) to be processed or imaged.

6. The method according to claim 5, wherein the superabsorbent polymer is selected from the group consisting of polyacrylates, polyacrylamides, polymethacrylates, polymethylmethacrylates, polyalkylmethacrylates, polyvinyl alcohols, hydroxyalkylpropiophenones, cross-linked polyethylene oxides, polyethylene glycols, polystyrenes, polyurethanes, cellulose, cellulose esters, cellulose ethers, starch, xanthan gum and their mixtures.

7. The method according to claim 5, wherein the gas precursor is selected from the group consisting of water; liquid C5 to C16 alkanes; liquid C4 to C9 cycloalkanes; liquid aromatics such as benzene, toluene, xylene; liquid esters such as methyl acetate, methyl nitroacetate, ethyl acetate, ethyl nitroacetate; liquid Cl to C9 alcohols such as methanol, ethanol, propanol, isopropanol, butanol; liquid phenols; liquid carboxylic acids such as C1-C12 carboxylic acids, trifluoroacetic acid; and liquid organometallic compounds where the definition of “liquid” refers to a pressure of 101,325 Pa and a temperature of 50° C., preferably at 25° C.

8. A method for storing a superabsorbent polymer of a gaseous or liquid gas precursor in focused charged particle beam devices.

9. The method according to claim 8, wherein the superabsorbent polymer is selected from the group consisting of polyacrylates, polyacrylamides, polymethacrylates, polymethyl methacrylates, polyalkyl methacrylates, polyvinyl alcohols, hydroxyalkylpropiophenones, cross-linked polyethylene oxides, polyethylene glycols, polystyrenes, polyurethanes, cellulose, cellulose esters, cellulose ethers, starch, xanthan gum and their mixtures.

10. The method according to claim 8, wherein the gas precursor is selected from the group consisting of water; liquid alkanes C5 to C16; liquid cycloalkanes C4 to C9; liquid aromatics such as benzene, toluene, xylene; liquid esters such as methyl acetate, methyl nitroacetate, ethyl acetate, ethyl nitroacetate; Cl to C9 liquid alcohols such as methanol, ethanol, propanol, isopropanol, butanol; liquid phenols; liquid carboxylic acids such as C1-C12 carboxylic acids, trifluoroacetic acid; and liquid organometallic compounds, where the definition of “liquid” refers to a pressure of 101,325 Pa and a temperature of 50° C., preferably at 25° C.
